(19) United States
(12) Patent Application Publication
(10) Pub. No.: US 2005/0213783 A1
(43) Pub. Date: Sep. 29, 2005

(54) Transmission drive line for low level audio analog electrical signals

(76) Inventor: William J. Walsh, Roanoke, VA (US)

Correspondence Address: WILLIAM J. WALSH, 3516 WELLINGTON DR. SE, ROANOKE, VA, 24014, US

(21) Appl. No.: 11/078,772

(22) Filed: Mar. 14, 2005

Related U.S. Application Data
(60) Provisional application No. 60/556,771, filed on Mar. 29, 2004.

(51) Int. Cl. H03F 21/00

(52) U.S. Cl. 381/120

(57) ABSTRACT

An electronically-enhanced cable of known characteristic impedance that is used to interconnect low level signals between the generating source and a pre-amplifier or amplifier with minimal noise-pick-up or cross-over distortion. The electronic enhancement means being integral with the cable and such that the voltage gain of the source signals is maintained at unity while the signal current is amplified 1000 or more times.

### BACKGROUND OF THE INVENTION

The present invention relates to the art of using electronically augmented cables to faithfully transmit low-level analog audio signals between various electronic components used in high quality sound reproduction systems. In many applications the signal levels are of the order of millivolts, must be transmitted over relatively long distances, and in electrically noisy environments.

One typical audio application involves the electrical interconnection of low-level audio signals from a recording studio microphone to a preamplifier. A much more widespread application is the cable interconnection of audio analog signals from phonographs, tuners, VCR's or CD players to a pre-amplifier in stereo or other entertainment systems.

It has long been recognized that each component of an audio system, starting with the signal reproduction source on through the various stages of amplification and finally to the loudspeaker or recording devices, may introduce noise, distortion, bandwidth loss or other forms of signal corruption unless careful precautions are taken in the design, manufacture and use of these audio system components. Since the first introduction of “Hi-Fi” systems over fifty years ago, great improvements have been made in the signal processing quality of each of these audio system components. But most audiophiles would agree that even the exclusive use of the most carefully engineered components in audio system components, still frequently fails to deliver “live, concert hall realism”.

For many years it was assumed that the interconnect cables used in these systems played an insignificant role in faithful signal transmission so long as they were reasonably good electrical conductors. Thus, many systems were interconnected with little better than ordinary household lamp cord or the equivalent. But in recent years there has been a serious focus on the transmission behavior of interconnects. These studies have resulted in a general recognition among engineers and audiophiles that in otherwise high quality audio systems the use of ordinary electrical wire for component interconnection noticeably degrades overall system performance. These developments have led to a number of observations regarding interconnect cables in general. In particular it is now widely recognized that:
1) All cables have an unavoidable leakage capacitance that increases in direct proportion to their length. This manifests itself in a “low-pass” filter characteristic which may cause a signal “roll-off” within the audio band in interconnects longer than a few meters and driven from a relatively high impedance source.
2) Under particular operating conditions an interconnect can function as an antenna picking up radiated electromagnetic signals from such low frequency noise sources as household appliance motors and fluorescent lighting systems. Under certain other conditions high frequency signals from radio transmissions and computer systems also cause signal corruption.

It is also known that the human ear is capable of comprehending acoustical sound levels that vary as much as 10,000,000 to one (140 db) in intensity over significant portions of the 20,000 Hz range of the audio spectrum. Thus, with a quiet background we can comprehend sounds as gentle as the rustle of tree leaves in a slight breeze all the way up to the piercing roar of a jet-airplane on take-off. Because of this extremely wide dynamic sensitivity any even slightly noise corrupted, or “rolled-off” electrical signal interferes with listener enjoyment when converted to an audio signal.

A long-employed solution for protecting low-level analog and digital electrical signals from radiated noise corruption has been to use shielded cables of the coaxial variety or, alternately, multi-strand cables woven in a “Litz braid” configuration between the originating signal source and the electronic amplifier. In general, depending on design and materials employed, this results in varying degrees of effectiveness in protecting signal transmissions from external corrupting signals. However, as will be discussed further in succeeding paragraphs even in the best noise protected cables audiophiles find tonal variations introduced by these cables that undesirably “color” the music and its stereophonic realism.

A well-known technique is widely used in industrial, scientific and computing systems to deal with the earlier-mentioned problem of capacitive roll-off. This technique involves resistively terminating the cable in its characteristic impedance, and driving the cable from a signal source whose output impedance is also matched to this characteristic impedance. In a cable with negligible resistive losses the characteristic impedance is determined by the square root of the ratio of the cable's inductance to its capacitance. Typical values of characteristic impedance for practical cable range from about 30 ohms to several hundred ohms, depending on geometry and construction materials employed. When such a condition is met it is well established that capacitive roll-off problems can be virtually eliminated even for cables that are tens of meters long. Unfortunately, however, it is generally agreed among audiophiles that such coaxial cables suffer from an audible clarity defect known in the art as poor “sound-staging”.

As an improved alternative to coaxial cables, multi-strand, braided cables woven in a “Litz” configuration are widely used. The Litz braiding configuration has long been known to reduce external noise pick-up by a mutual noise cancellation technique among the strands. Such braided cables may also have the advantage of reducing “skin effect” as a result of their multi-strand current splitting configuration. But even these cables are often found wanting in sonic performance. This fact has led others to advocate the use of highly purified silver or oxygen free copper conductors and carefully chosen insulating materials such as high grade Teflon in the construction and manufacture of the cables. Still others have focused on improvements in the mechanical integrity of the cable or its terminating plug connection means at each end of the cable. While incremental improvements in sound performance are often cited, few would claim that a cable with perfect signal “transparency” has been developed.

### SUMMARY OF INVENTION

The objective of the subject invention is to significantly improve the signal fidelity of audio interconnect cables or their “transparency” over the current state of the art. This is accomplished by a unique amplifier circuit that is integral with an interconnect cable that has been terminated in its characteristic impedance. The amplification process is such that the current through the interconnecting cable is increased a thousand times or more while maintaining unity voltage gain of the transmitted signal between sending and receiving ends of the interconnect. The driving amplifier circuit utilizes a dual operational amplifier technique that substantially eliminates “zero cross-over” distortion.

### DESCRIPTION OF THE FIGURES

FIG. 1 shows a circuit representation of a typical audio low-level signal source such as a CD player driving a high input impedance pre-/amplier.

FIG. 2 shows schematically the resulting current in an interconnect cable when the source and load impedance are made equal.

FIG. 3 is a distributed L-C circuit representation of a high quality interconnect cable whose series and shunt resistance elements are negligible.

FIG. 4 is a general circuit representation of the subject invention.

FIG. 5 is a circuit representation of the integrated amplifier interconnect combination wherein the amplifier output impedance and the interconnect's terminating resistance have been made equal to the characteristic impedance of the cable.

FIG. 6 is a schematic of a dual operational amplifier circuit capable of driving a low impedance load with negligible zero cross-over distortion.

FIG. 7 illustrates a sine wave with noticeable “zero crossover” distortion.

FIG. 8 shows a schematic view of the key components of the subject invention which serves as an “active” interconnect between a CD player and a pre-/amplifier.

### DETAILED DESCRIPTION OF THE INVENTION

The basic idea underlying the subject invention stems from the recognition that the typical maximum signal amplitude from an audio source, say a tuner or CD player is of the order of five volts or less with such signal sources having an output impedance typically in the range of hundreds of ohms. Moreover, the input impedance of the receiving unit such as a pre-amplifier or amplifier is of the order of 100,000 ohms or greater. As FIG. 1 illustrates, under these conditions the signal current through the interconnecting cable is limited to the order of 50 microamperes or less. This is to be contrasted with the current, which flows from the output of a typical amplifier to a loud speaker with a power capability of 100 watts or more. In this latter situation the signal current flowing through the connecting cable can be as much as five amperes or more.

After much experimentation, the inventor has found that a dramatically improved, “concert-hall realism” in audio listening quality is achieved when the signal current flowing through a cable between a CD player or other low-level audio source and the pre-amplifier or amplifier is increased by several orders of magnitude. Typically, this means increasing the signal current from tens of microamperes up into the range of tens of milliamperes. It should be understood that this current transformation is intended to take place without in any way modifying the voltage amplitude of the original signal. That is to say that a signal power gain of thousand or more is achieved while maintaining unity gain of the originating voltage signal. In the subject invention this is accomplished by an electronic current transformation means that is integral with the cable. From a listening standpoint when this transformation has been implemented, it is found that there is a great improvement in overall listening clarity, as well as better “sound staging”—that is audio separation of multi-voices and instruments. This is particularly true in the mid frequency range of the audio band where the human ear is especially sensitive.

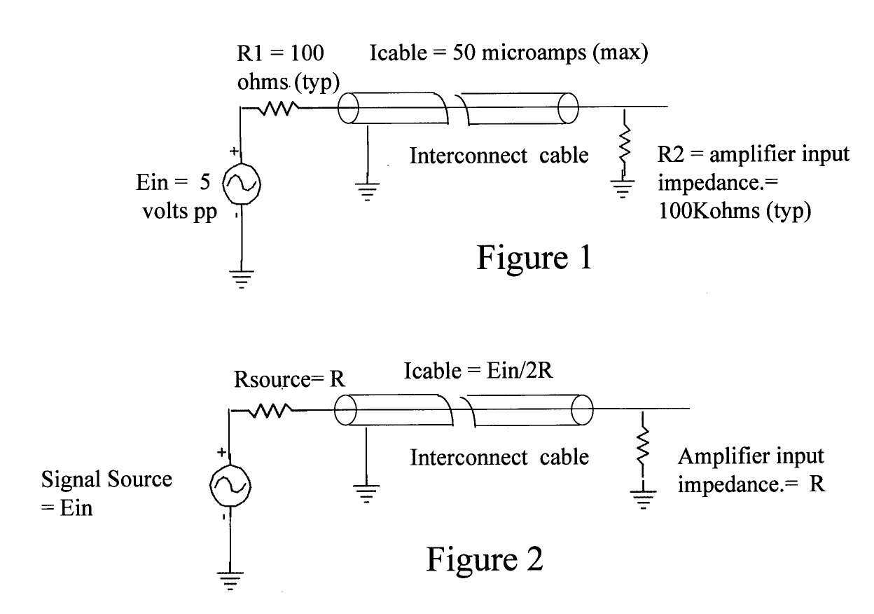

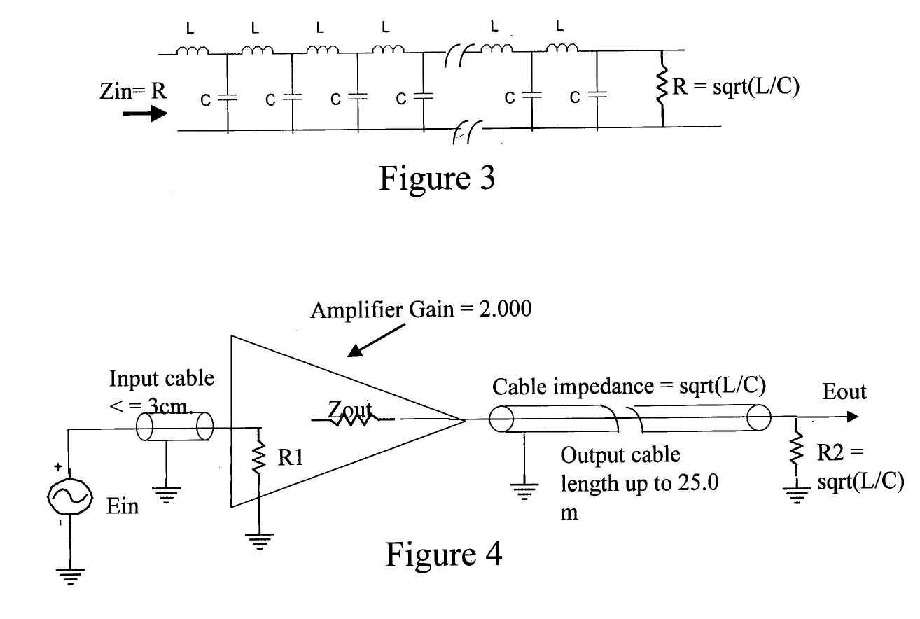

Moreover, the subject invention provides a practical implementation for increasing signal current robustness by a factor of one-thousand or more, while still maintaining unity voltage gain, and transmitting it through an interconnecting cable without introducing signal distortion. To this end the invention makes use of three important concepts:
1. It is well known that the more robust a current signal flowing through an interconnection cable is, the less it is subject to corrupting external noise sources. It is further theorized that a much more robust current signal is less subject to distortions created by known electronic conduction deficits within the cable itself due to material impurities and atomic structural irregularities. It is believed that these atomic level irregularities cause random distortions to the desired audio signal, and which, although very small, are nevertheless detectable to the listener due to the extreme sensitivity and dynamic range of the human ear.
2. It is also well known that maximum energy transfer between an electrical energy source and the load it is driving occurs when the impedance of the load is exactly equal to the impedance of the driving source. This is illustrated in FIG. 2, for a purely resistive source impedance.
3. In transmission line cable theory it is also established that a loss-less cable appears as a purely resistive load at its input end when terminated at its output end with a resistor that is equal to the square root of the ratio of the cables inductance per unit length to its capacitance per unit length. FIG. 3 illustrates this situation. Of great importance in some audio applications is the fact that these results holds true independent of the cable's length. It should also be noted that a well-designed audio cable is an excellent approximation to a loss-less cable. That is to say its series resistance is very nearly zero and its shunt resistance is practically infinite.
4. There is a further advantage to terminating a cable in its characteristic impedance that is very important in the actualization of the subject invention: A cable properly matched with its characteristic impedance at both its source and receiving ends transfers the maximum amount of available electrical energy between the source and the load. Such a cable also behaves as a reflection-less and distortion-less line, since no net energy per cycle is capacitively or inductively stored along the length of the cable. In situations where the signal source is a sinusoid of fixed amplitude and frequency any mismatch between the characteristic impedance of the cable and its terminating impedance manifests itself as a simple phase shift between the input signal and the output signal. However, a signal that represents music, voice or other non-recurring analog waveform presents a much different problem. These signals are made up of mixed signal sources, complex waveforms of varying amplitudes, frequencies, and their harmonics, that are interrupted with pauses of varying lengths. Thus, in the case of music, any excess capacitive or inductive energy stored in the cable discharges itself into the load impedance in an unpredictable fashion. When these signals are translated into sound, the listener hears them as a dulling, smearing or loss of articulation in the music.

FIG. 4 illustrates in block diagram form the overall concept of the subject invention and its basic elements. On the left hand side is represented an audio signal source such as a microphone, CD player or other analog audio signal source. The signal source is connected to the input of an amplifier processing circuit by a cable, whose length is as short as mechanically practical, typically, several centimeters. The purpose of keeping this length short is to minimize any signal deterioration due to capacitive roll-off or noise pick-up. The receiving end of this short cable is connected to a precision operational amplifier circuit of gain two, and with an input impedance of 100,000 ohms or greater. The amplifier circuit is designed such that it is capable of delivering a power gain greater than one thousand while still maintaining unity voltage gain and without introducing any audible distortion. By design the output impedance of this amplifier is made equal to the characteristic impedance of the cable to which it is attached. Typically, this impedance is between 25 and 100 ohms and the overall length of the interconnecting cable ranges in length from one to 25 meters or more. At the receiving end of the interconnecting cable a terminating resistive load is incorporated into the cable plug. This termination load is also chosen to be equal to the characteristic impedance of the cable. Also, connected to the interconnection cable at its receiving end is typically an amplifier or pre-amplifier. The input impedance of such devices are typically 50,000 ohms or greater. In any event this input impedance has negligible effect when paralleled with the low terminating resistance of the cable.

In order to distinguish an amplifier/cable system such as described above from an ordinary, passive audio inter-connect cable, the inventor has chosen the name “Transmission Drive Line” or “TDL” for the invention. This identifying terminology will be used throughout the application.

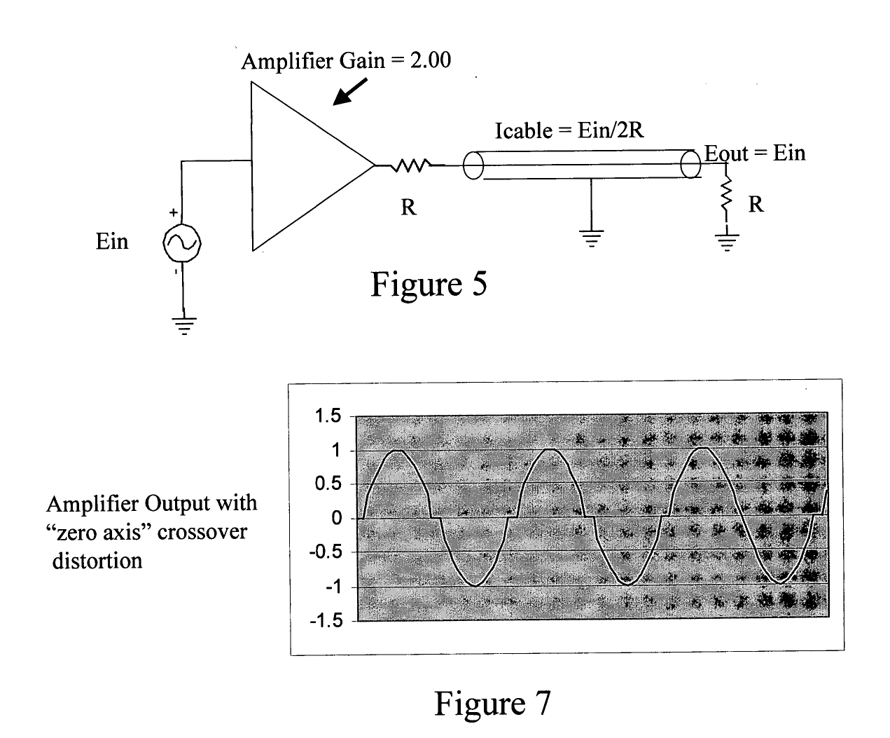

As illustrated by the equivalent circuit of FIG. 5, it will be seen that a source signal of amplitude Ein that is connected to a precision amplifier of gain two will also appear at the receiving terminals of the cable with an amplitude Ein due to the combined result of the amplifier's precision voltage gain of two and the voltage divider action between the said amplifier's output impedance and the cable's terminating impedance, which by design are made co-equal. It will also be noted that the signal current passing through the interconnecting cable and flowing through the load is given by:
Icable=2×Ein/(Zo+Zload)=Ein/R (eqn a)

By way of example a CD player with a peak signal amplitude of plus or minus 5 volts operating into an amplifier/matched-cable TDL combination with a characteristic impedance of say 50 ohms will have a peak current flowing through the cable of 100 milliamperes.

The realization of a practical and commercial Transmission Drive Line for audio use must meet a number of demanding requirements. Among these requirements are:
1) Audiophiles prefer to select the individual components that make-up an audio system from a variety of manufacturers, each of whom offers many different models within a given product family. Literally there are dozens of suppliers of CD Players, turntables, microphones, inter-connect cables, pre-amplifiers, amplifiers etc. Moreover, there is no industry wide standardization of input and output impedances of these products that must be inter-connected. For example, a cursory survey of the output impedances of CD players from a dozen manufacturers showed a range of from 15 ohms up to 850 ohms. Similarly the input impedance of a group of pre-amplifiers went from a low of 50 kilohms up to 500 kilohms. Situations similar to audio equipment also occur with other analog signal transducers that are interconnected with their associated amplifying/conditioning equipments. Thus, a TDL must be able to handle these varying input and output impedances of the equipments to which they are attached.
2) Cables connecting an audio signal source to a pre-amplifier or other device have demanding marketplace expectations by audiophiles that transcend their ability to faithfully transmit an audio signal without distortion or external noise corruption. In particular it is expected that they will be mechanically durable, flexible and aesthetically pleasing. These additional requirements place stringent envelope and packaging constraints on the amplifier circuitry that is integrated into the cable of a Transmission Drive Line. In particular the packaging of the amplifier circuitry must be as small in linear dimensions and as slender as possible to meet these requirements.
3) A Transmission Drive Line (TDL) requires up to 100 milliamperes of current in normal operation with supply voltages greater than or equal to plus or minus 12 volts. Because audio equipment is used for many hours at a time a well-regulated external power supply is generally required.
4) It is essential that the amplifier portion of the TDL not introduce any detectable “crossover” or other forms of signal distortion. And,
5) A Transmission Drive Line should be directly substitutable for an ordinary interconnect cable without having to adjust the volume controls of the pre-amplifier or amplifier to which it is connected or make any other equipment modifications. In other words it should have a “plug and play” compatibility.

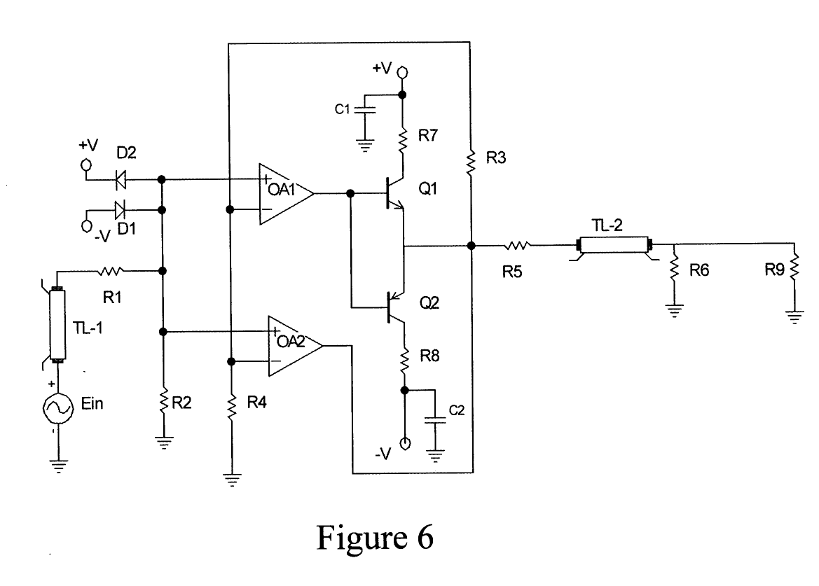

FIG. 6, shows an integrated high performance dual operational amplifier circuit capable of driving a low impedance cable with negligible distortion. The operational amplifier chosen for application purposes is a TL082, although there are many other dual amplifier packages that could be utilized. It will be noted that both the positive and negative input terminals of the operational amplifiers are connected in parallel while their outputs are connected to separate nodes. The output of the first amplifier, designated as OA1, is connected to the base terminals of a complementary NPN-PNP pair of emitter followers. However, the output of operational amplifier OA2 is connected to the emitter terminals of the complementary NPN-PNP pair. The reason for this particular circuit configuration is as follows: Typically, a single integrated circuit operational amplifier will have an output current limitation of 10 to 15 milliamperes. The usual remedy where higher currents are required, as in the present instance, is to use an external complementary pair of emitter followers within the feedback loop. However, this is only partially successful, because transistors do not conduct significantly until the base-emitter voltage is forward-biased by about 0.7 volts. Thus, in the single operational amplifier circuit that feeds a complementary emitter follower pair configuration there is a 1.4 volt dead-band as the PNP and NPN devices alternately switch-on to full conduction on each half cycle. When a sine wave is applied to such a circuit there is a dead band on the output side of the circuit as the signal wave passes from a negative to positive voltage about the zero volt level. FIG. 7 illustrates this “crossover distortion” effect. The nature of crossover distortion is to introduce significant third harmonic signals, which are very noticeable and unpleasant to audio listening. Some improvements in crossover distortion may be obtained by using very fast rise-time operational amplifiers that speed through the dead-band zone. Other schemes involve techniques to appropriately pre-bias the emitter followers. But still some distortion remains.

The “push and shove” dual operational circuit of FIG. 6 provides a much more satisfactory result in eliminating distortion. It takes advantage of the fact that a single op-amp can provide a current of, perhaps, 15 milliamperes to an impedance as low as 100 ohms, over a voltage range of plus or minus one volt before current-limiting and introducing distortion. In the circuit of FIG. 6, OA2 bypasses the emitter follower pair and drives the load directly for low signal amplitudes. When signal amplitudes greater that plus or minus one volt occur, the emitter followers are completely forward biased and OA1 is easily able to provide the needed base current to provide output currents of up to 100 milliamperes at the higher signal amplitudes. It should be noted that experimentally the circuit of FIG. 6 is able to operate at frequencies in excess of 70 kilohertz before distortion is apparent.

Resistor R5 is also connected to the emitter terminals of the pair and is chosen to be equal to the characteristic impedance of the cable,TL-2, to which its other end is attached. For illustration purposes, this value is chosen to be 50 ohms but may range from 20 to several hundred ohms depending on the characteristic impedance of the cable to which it is matched. The cable itself is terminated at its opposite end by resistor R6, whose value is also selected to be equal to the characteristic impedance of the cable, TL-2. In the subject invention R6 is housed within the “RCA” type plug connector frequently used in audio applications. Both collectors of the NPN-PNP pair are connected to current limiting resistors R7 and R8 (for example 47 ohms), which are in turn connected to their respective positive and negative power supplies, V(+) and V(−). These voltages are typically +15 and −15 volts to easily accommodate anticipated maximum voltage swings of the input signal. Decoupling capacitors Cl and C2 are also shown in FIG. 6 in keeping with good standard practice.

Resistors R3 and R4 “close the loop” around the operational amplifier pair with resistor R3 connected between the emitter terminals of the complementary NPN-PNP pair and both negative inputs of the operational amplifiers. Resistor R4 is connected between the joined inverting input terminals of the operational amplifier pair and the ground point of the circuit. For application purposes R3 has a value of 18 K and R4 has a value of 15 K. As shown by equation (b), below, the choice of these values is partially dictated by the choice of R1 and R2.

At the input signal end of the circuit is a voltage divider comprised of resistors R1 and R2. Resistor R1 connects between the signal input terminal, via the purposely short input cable, TL-1 and the joined positive inputs of the operational amplifiers. R2 connects between the same positive inputs and signal ground. R1 has a value of 10K and R2 a value equal to 100K. Clamping diodes, D1 and D2, are included in the circuit to prevent damage to the operational amplifiers due to the accidental application of input voltages that exceed the power supply limits. Similarly Resistor R1 also prevents circuit damage in the event of excessive current flow.

The voltage V2 appearing at the common node of the emitter follower pairs for the circuit of FIG. 6 with a signal input voltage Ein applied to the non-inverting terminals of the operational amplifiers can be shown to be:
V2=Ein×R2/(R1+R2)×(1+R3/R4) eqn-b

For the values chosen for R1, R2, R3 and R4 of FIG. 6, equation (b) yields:
V2=Ein×(10k/110k)×(1+1.8k/1.5k)=2.0×Ein

It will be understood that the choice for resistors R1, R2, R3, and R4 is arbitrary so long as eqn-b yields a voltage V2 that is exactly twice Ein.

Looking back from the emitter follower pair it is known that the output impedance of a closed loop operational amplifier circuit approaches zero due to the nearly infinite gain of the operational amplifiers. Resistor R9 represents the input impedance of the next-stage amplifier/processor which is at the receiving end of the interconnection cable. Typically the value of R9 ranges between a low of 50 K ohms and 1 megohm. In any event it has negligible effect when paralleled with the cable terminating resistor R6. It is, therefore, justifiable to adopt the equivalent circuit of FIG. 5 to analyze the signal that appears across the terminating resistor R6 at the output end of the cable when driven by an equal source impedance, R5.

By reference again to FIG. 5, it is seen that the output voltage, Eout, appearing across R6 is equal Ein and the desired unity voltage gain is achieved. And as also been previously demonstrated in connection with the analysis of FIG. 5, the current flowing through the cable is:
Icable=Ein/R. equation (a) (repeated)

For a typical plus or minus 5 volt input signal, amplifier precision gain of 2, and output and terminating impedances of 50 ohms, the peak current flowing through the cable is of the order of 100 milliamperes. Thus, the circuit of FIG. 6 provides a very low distortion method to maintain unity voltage gain between the signal transducer and the receiving amplifier/processor, while increasing the cable current by three orders of magnitude above that which would normally flow as a result of the typical 100K ohm input impedance of an amplifier or other signal processor at the receiving end of the cable.

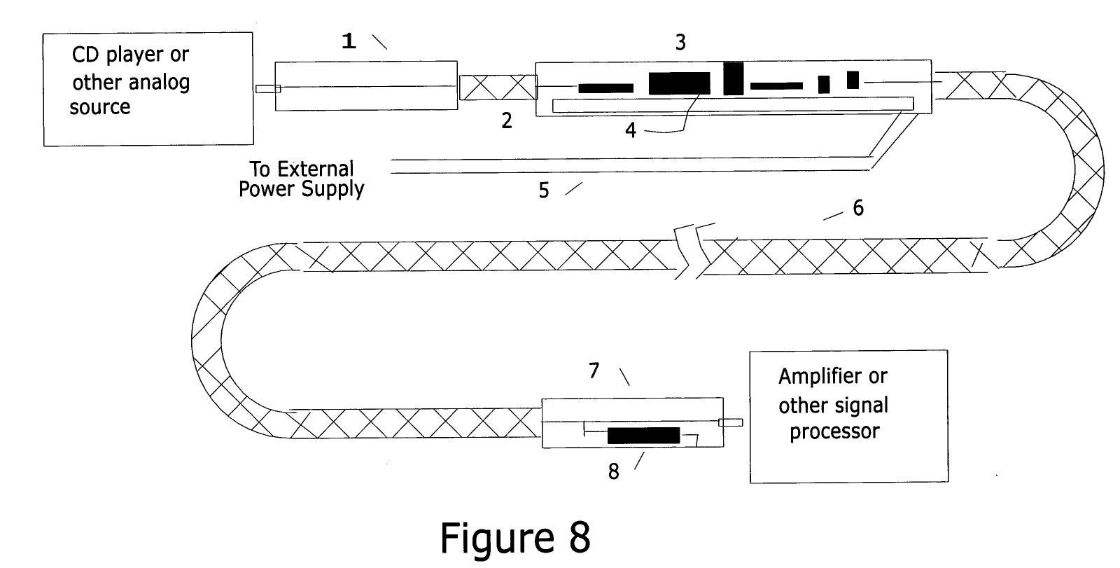

FIG. 8 is a pictorial view of a Transmission Drive Line as implemented. At the left top of FIG. 8, there is shown an analog signal source/transducer such as a CD player. It is connected with a standard RCA Plug (1) and a purposely short cable (2), to the input of The TDL current amplifier (3). This input cable length is ideally less than one inch. The TDL current amplifier (3) is totally enclosed within a housing approximately 3.5 inches in length and 0.5 inches in diameter. Internally, there is circuitry, (4), that is shown schematically in FIG. 6 and which is mounted on a pc board. A small cable (5) supplies needed power to the current amplifier circuitry from an external “desk-top” power supply. The output of the current amplification circuit is connected to a braided or shielded cable (6), whose characteristic impedance is known. This cable is typically 0.40 inches in diameter and may range in length from 1.5 feet up to 50 feet, depending on the particular application. At the output end of the cable (6) is a second RCA connector (7). Connector (7) has a resistor (8) internal to it that connects between the signal line and ground. The impedance of this resistor (8) is chosen to match the characteristic impedance of the cable (6) to which it is attached and is also of the same value as the output impedance of the current amplifier circuit (4). The output of the RCA connector (7) is plugged into an amplifier or other signal processor.

Although the invention has herein above been described with respect to the illustrated embodiments, it will be understood to those having ordinary skill in the art that the invention is capable of modification and variation and is limited by only the following claims.

1) An integrated system comprising an audio signal cable resistively terminated in its characteristic impedance and driven by a high input impedance amplifier circuit with a precision voltage gain of two and with an output impedance of said amplifier matched to the characteristic impedance of said cable. Said system having a unity voltage gain between signal input and received output, and a current gain of one thousand or more over signal bandwidths of interest and with negligible distortion.

2) A system as described in claim 1 comprising a current amplification circuit, and an impedance matched cable and termination means, which are integrated in a single unit along the length of the cable. Said current amplification circuitry being physically integrated into the interconnection cable within the immediate proximity of the cable's sending end and the cable's matched termination resistance being incorporated into the connection plug at the receiving end of the cable.

3) A system as described in claim one whereby a current several orders of magnitude greater than would flow in an ordinary interconnect cable is used as the means to transmit a signal from the transducer source to the next-stage amplifying and processing equipment. Use of such high current means being a much more reliable method of faithfully transmitting an electrical signal without loss or distortion.

4) A system as described in claim one whereby, the impedances at the source and receiving ends of the interconnect cable are matched to said cable's characteristic impedance in order to substantially improve the fidelity of audio signal transmission between sending and receiving ends of said cable.

5) An integrated amplifier and interconnect cable system as described in claim one whereby a “plug and play” capability is achieved such that no change in audio volume settings of the signal source or other processing components is necessary from that required for a strictly passive interconnect cable.

6) A dual operational amplifier circuit with a precision gain of two and precisely controlled output impedance that is employed in a “push and shove” tandem configuration driving a complementary pair of emitter followers in a closed loop configuration with one amplifier output driving the emitters of the complementary pair and with the second amplifier output the base terminals of said complementary pair such that low impedance loads can be driven with minimal cross-over and other forms of signal distortion.
